(19) United States
(12) Patent Application Publication
(10) Pub. No.: US 2025/0354011 A1
(43) Pub. Date: Nov. 20, 2025

(54) FLAME RETARDED RESIN COMPOSITION AND ARTICLES MADE THEREFROM

(71) Applicant: ICL-IP AMERICA INC., Tarrytown, NY (US)

(72) Inventors: Andrew PIOTROWSKI, Yorktown Heights, NY (US); Meng ZHANG, White Plains, NY (US); Joseph ZILBERMAN, Haifa (IL); Eran Gluz, Hod Hasharon (IL)

(21) Appl. No.: 18/869,557

(22) PCT Filed: Jul. 17, 2023
(86) PCT No.: PCT/US2023/027875

§ 371 Date: Nov. 26, 2024

Related U.S. Application Data
(60) Provisional application No. 63/391,066, filed on Jul. 21, 2022.

(51) Int. Cl. C08L 71/12; C08K 5/3492; C08K 5/53; C08L 9/00

(52) U.S. Cl. CPC C08L 71/12; C08K 5/34924; C08K 5/53; C08L 9/00; C08L 2201/02; C08L 2203/20

(57) ABSTRACT

There is provided herein a flame retarded, halogen free resin composition comprising
(a) a free radically polymerizable monomer or oligomer; and,
(b) 4-vinylbenzyl diphenylphosphine oxide having the formula (I):

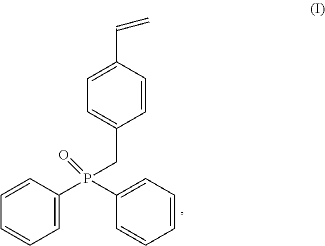 [SMILES: C=Cc1ccc(CP(=O)(c2ccccc2)c2ccccc2)cc1]

and wherein the composition is in the absence of a maleimide resin. There is also provided an article which may be made from the composition, which article can be a prepreg, a resin film, a laminate, or a printed circuit board. The said article has low dielectric loss at a very high frequency.

### FIELD OF THE INVENTION

The present invention relates to resin composition, more specifically flame retarded resin compositions which are used in the field of electronics, with low dielectric loss, high Tg and high heat resistance.

### BACKGROUND OF THE INVENTION

With the widespread popularity of 5G communication technology, electronic products are changing with each passing day, requiring faster data transmission speed and higher system operating frequencies. At the same time, lead-free soldering requires materials to withstand higher temperatures. In order to meet higher requirements, high-frequency, high-speed, low-loss, high-Tg copper clad laminates have to meet the basic conditions for such applications.

The epoxy phenolic resin system, which is commonly used in copper-clad laminate (CCL), has a high dielectric loss, which limits its application in the field of high frequency and high-speed applications. Many resins developed to replace epoxy-based systems are more flammable than epoxy, and require use of very efficient flame retardants, to meet the requirements of electronic communication technology. Most of such flame retardants have negative effects on electrical properties.

For example, polyphenylene oxide (PPO) resins are widely used for making low dielectric copper-clad laminates. However, copper-clad laminates made solely from a PPO resin have a low glass transition temperature (Tg), and also, PPO resin has shown poor compatibility with other resins, which causes the problems of high ratio of thermal expansion and poor thermal resistance. As a result, polyphenylene oxide resin alone has failed to meet the demands of new generation high frequency and low dielectric circuit boards.

The goal of the present invention is to provide a flame retardant that is compatible with PPO resins and provides composition with Df lower than 0.003 and Dk lower that 2.8 at a very high frequency of 80 GHz., while maintaining high thermal stability with the onset of decomposition higher than 370° C.

Bismaleimide has been introduced in an attempt to provide a lower ratio of thermal expansion and a high thermal resistance in resin systems. But this solution has resulted in the deterioration of the dielectric properties of the resin. Thus, vinyl terminated PPO has been used to chemically bond to resins such as polybutadiene, SBR rubber or C5 aliphatic resins. This has eliminated the compatibility problems. The low Tg has been addressed by using crosslinking agents such as triallyl isocyanurate.

The problem is that such a combination of resins is highly flammable. Finding a flame retardant that is compatible with such crosslinked resin which does not result in deterioration of electrical properties or thermal stability is a difficult task. Additive flame retardants must have very high melting points in order not to lower the Tg. They also must be easily dispersible in varnish. To achieve good dispersibility of the high melting additive flame retardant in the varnish it is necessary to perform milling. This operation is aimed at reducing the particle size to less than several microns. Such fine milling requires a specially designed expensive equipment and is accompanied by losses of the milled product. On the other hand, reactive flame retardants can become incorporated in the resin providing uniform distribution, so that no dispersibility problems take place. However, finding such compounds that also have no negative effect on electrical properties, Tg, and thermal stability is a major challenge. In addition, compatibility of the flame retardant with other varnish components is equally important.

Accordingly, there is a need to develop a material for copper-clad laminates that overcomes most of the aforesaid technical problems.

### BRIEF SUMMARY OF THE INVENTION

The invention herein belongs to the technical field of laminates, and relates to a thermosetting resin composition, a prepreg and a copper-clad laminate using the thermosetting resin composition.

There is provided herein a composition comprising:
(a) a free radically polymerizable monomer or oligomer; and,
(b) 4-vinylbenzyl diphenylphosphine oxide having the formula (I):

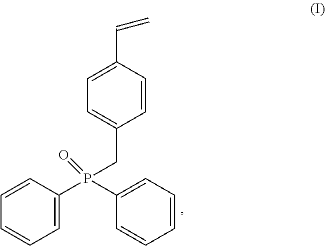 [SMILES: C=Cc1ccc(CP(=O)(c2ccccc2)c2ccccc2)cc1]

and wherein the composition is in the absence of a maleimide resin.

There is also provided herein a process making a laminate that contains the composition described herein, said process comprising impregnating the composition into a filler material, to form a prepreg, followed by processing the prepreg at elevated temperature to promote partial cure to a B-stage and then laminating two or more of said prepregs at elevated pressure and temperature to form a laminate. The said laminate has low dielectric loss at a very high frequency.

### DETAILED DESCRIPTION OF THE INVENTION

The inventors herein have discovered that 4-vinylbenzyl diphenylphosphine oxide as shown in the structure of formula (I) above, participates in the curing process with the free radically polymerizable monomer or oligomer (a), most preferably vinyl-terminated PPO in an amount of at least 40 weight %. This curing process produces a composition having an unexpectedly low Df at high frequencies such as 80 GHz. Since 4-vinylbenzyl diphenylphosphine oxide is incorporated into the vinyl-terminated PPO resin during curing process there is no need for it to have high melting point.

In the present invention, 4-vinylbenzyl diphenylphosphine oxide is added to the varnish and co-cured with the free radically polymerizable monomer or oligomer described herein. As a result, a resin composition is obtained, which is a composite material having a low thermal expansion ratio, a high heat resistance, a high glass transition temperature, a low dielectric constant which is equal to or less than 2.72 at 80 GHz, and an unexpectedly low dissipation factor of 0.0022 at 80 GHz.

It will be understood herein that all ranges herein include all subranges there between and also any combination of endpoints of said ranges.

Unless indicated otherwise, all weight percentages herein are based on the total weight of the reaction components.

All temperatures herein are room temperature unless indicated otherwise.

All viscosity measurements recited herein are conducted at 25 degrees Celsius and using a Brookfield capillary viscometer. All pressures indicated herein are 1 atmosphere at sea level and at 25 degrees Celsius unless indicated otherwise.

The free radically polymerizable monomer or oligomer (a) described herein comprises one or more unsaturated bonds per molecule. Unless otherwise specified, the unsaturated bond of the free radically polymerizable monomer or oligomer (a) is a reactive unsaturated bond, such as but not limited to a double bond with the potential of being crosslinked with other functional groups, such as an unsaturated carbon-carbon double bond with the potential of being crosslinked with other functional groups, but not limited thereto.

In one embodiment, the free radically polymerizable monomer or oligomer comprises a vinyl-terminated polyphenylene ether resin. The vinyl-terminated PPO resin is capped by vinyl groups at both ends. Examples of the vinyl-terminated polyphenylene ether resin include but are not limited to vinylbenzyl-terminated polyphenylene ether resin (e.g., OPE-2st available from Mitsubishi Gas Chemical Co., Inc.), methacrylate-terminated polyphenylene ether resin (e.g., SA9000 available from Sabic), vinylbenzyl-modified bisphenol A polyphenylene ether resin, vinyl-containing chain-extended polyphenylene ether resin, or a combination thereof. For example, the vinyl-terminated polyphenylene ether resin may be added to the 4-vinylbenzyl diphenylphosphine oxide having the formula (I) in any ratio as described above.

Most preferably, the free radically polymerizable monomer or oligomer (a) described herein can comprise vinyl-terminated PPO in an amount of at least 40 weight %.

In addition to the vinyl-terminated PPO in an amount of at least 40 weight %, the free radically polymerizable monomer or oligomer (a) described herein can further comprise other components as described herein below.

In one embodiment herein the free radically polymerizable monomer or oligomer (a) can further be such that it contains vinyl group or an allyl group, preferably an alkene or diene monomer or oligomer. More preferably the free radically polymerizable monomer or oligomer is selected from the group consisting of a vinyl-containing compound, an allyl containing compound, an acrylate resin, a polyolefin, and combinations thereof.

Even more preferably the free radically polymerizable monomer or oligomer can further be selected from the group consisting of styrene, t-butyl styrene, divinylbenzene, bis(vinylbenzyl) ether, bis(vinylphenyl)ethane, 1,2,4-trivinylcyclohexane, vinyl-terminated polyphenylene ether resin, vinylbenzyl-terminated polyphenylene ether resin, methacrylate terminated polyphenylene ether resin, vinylbenzyl-modified bisphenol A polyphenylene ether resin, polybutadiene, isoprene, polyisoprene, piperylene, trans-1,3-pentadiene, cis-1,3-pentadiene, 2-methyl-2-butene, dicyclopentadiene, cyclopentadiene, cyclopentene, triallyl isocyanurate, triallyl cyanurate, diallyl bisphenol A, allyl-modified tetramethylbiphenol, allyl-containing novolac resin, an allyl-containing dicycloisoprene novolac resin, dodecyl methacrylate, octadecyl methacrylate, 2-phenoxyethyl methacrylate, tricylcodecane dimethanol diacrylate, tricyclodecane di(meth)acrylate, 1,1-dodecanediol dimethacrylate, trimethylol-propane trimethacrylate, styrene-butadiene-divinylbenzene terpolymer, vinyl-polybutadiene-urethane oligomer, styrene-butadiene copolymer, hydrogenated styrene-butadiene copolymer, styrene-isoprene copolymer, polybutadiene, methyl styrene copolymer, styrene-ethylene copolymer, styrene-propylene copolymer, styrene-butadiene-isoprene terpolymer, hydrogenated styrene-butadiene terpolymer, hydrogenated styrene-isoprene copolymer, hydrogenated styrene-butadiene-isoprene terpolymer, and combinations thereof.

According to the present disclosure, the type of the free radically polymerizable monomer or oligomer resin is not particularly limited provided it contains the 40 weight percent of vinyl-terminated PPO, and may comprise a small molecule vinyl-containing compound, an allyl-containing compound, an acrylate resin, a polyolefin, or a combination thereof.

In one embodiment, the free radically polymerizable monomer or oligomer comprises a small molecule vinyl-containing compound. The small molecule vinyl-containing compound as used herein refers to a vinyl-containing compound with a molecular weight of less than or equal to 1,000, preferably between 100 and 900 and more preferably between 100 and 800. According to the present disclosure, the small molecule vinyl-containing compound may include, but not limited to, divinylbenzene (DVB), bis(vinylbenzyl)ether (BVBE), bis(vinylphenyl)ethane (BVPE), 1,2,4-trivinyl cyclohexane (TVCH), or a combination thereof.

In one embodiment, the free radically polymerizable monomer or oligomer comprises an allyl-containing compound. The allyl-containing compound is a compound containing an allyl group and is not particularly limited, preferably being an allyl-containing resin having two or more allyl groups per molecule. The allyl-containing resin may also contain other functional groups, such as an epoxy group, a hydroxyl group, etc. Examples of the allyl-containing compound include but are not limited to triallyl isocyanurate (TAIC), triallyl cyanurate (TAC), diallyl bisphenol A, allyl-modified tetramethylbiphenol, an allyl-containing novolac resin, an allyl-containing dicycloisoprene novolac resin, or a combination thereof. Preferably, the allyl-containing compound comprises an allyl-modified tetramethylbiphenol, an allyl-containing dicycloisoprene novolac resin, or a combination thereof.

In one embodiment, the free radically polymerizable monomer or oligomer comprises an acrylate resin. The acrylate resin may comprise a mono-functional acrylate resin, a bifunctional acrylate resin, or a trifunctional acrylate resin, but not limited thereto. For example, the mono-functional acrylate resin may comprise, but not limited to, dodecyl methacrylate, octadecyl methacrylate, 2-phenoxyethyl methacrylate or a combination thereof. The bifunctional acrylate resin may comprise, but not limited to, tricyclodecane dimethanol diacrylate, 1,6-hexanediol diacrylate, 1,6-hexanediol dimethacrylate, 1,12-dodecanediol dimethacrylate or a combination thereof. The trifunctional acrylate resin may comprise trimethylolpropane trimethacrylate.

For example, the mono-functional acrylate resin may be a mono-functional long-chain alkyl acrylate sold by Sartomer under the tradenames SR313A, SR313B, SR313NS, SR324NS, SR335, and SR489D. For example, the bifunctional acrylate resin may be a bifunctional acrylate sold by Sartomer under the tradenames SR-833S, SR-238NS, SR-239 and SR-262. For example, the trifunctional acrylate resin may be a trifunctional acrylate sold by Sartomer under the tradename SR-350NS.

In one embodiment, the free radically polymerizable monomer or oligomer comprises a polyolefin. Examples of the polyolefin include but are not limited to a polymer containing one or more monomers selected from ethylene, propylene, 1-butene, 1-pentene, 1-hexene, 4-methyl-1-pentene, 1-octene, 1-decene and so on or, or a random polypropylene, ethylene-ethyl acrylate copolymer, etc. Examples include: styrene-butadiene-divinylbenzene terpolymer, styrene-butadiene-maleic anhydride terpolymer, vinyl-polybutadiene-urethane oligomer, styrene-butadiene copolymer, styrene-isoprene copolymer, polybutadiene (homopolymer of butadiene), maleic anhydride-butadiene copolymer, methyl styrene copolymer, styrene-ethylene copolymer, styrene-propylene copolymer, styrene-butadiene-isoprene terpolymer, or a combination thereof.

The polyolefin preferably includes a polyolefin with an elongation percentage (elongation %) of greater than or equal to 500%, such as but not limited to D-1117, D-1118, G-1652, G-1701, G-1702, G-1750, G-1765, G-1780, etc. In addition, the polyolefin preferably has an elongation percentage ranging from 500% to 1,500%.

The free radically polymerizable monomer or oligomer (a) and the 4-vinylbenzyl diphenylphosphine oxide having the formula (I) (b) may be present in any ratio. For example, the free radically polymerizable monomer or oligomer may be present in the composition in amounts of from 40 to about 95 weight percent, preferably from about 55 to about 90 weight percent and most preferably about 65 to about 85 weight percent, the 4-vinylbenzyl diphenylphosphine oxide having the formula (I) may be present in amounts of from 5 to about 60 weight percent, preferably from about 10 to about 45 weight percent and most preferably about 15 to about 35 weight percent

In one embodiment, the composition according to the present disclosure may optionally further comprise: epoxy resin, amine curing agent, phenol curing agent, anhydride curing agent, benzoxazine resin, cyanate ester resin, or any combination thereof, but not limited thereto.

In addition, the composition according to the present disclosure may optionally further comprise: inorganic filler, curing accelerator, solvent, silane coupling agent, coloring agent, or a combination thereof.

In one embodiment of the present disclosure, the composition may optionally further comprise inorganic filler, curing accelerator, solvent, molecular weight regulator, polymerization inhibitor, toughening agent, coupling agent or a combination thereof. Unless otherwise specified, relative to a total of 100 parts by weight of the free radically polymerizable monomer or oligomer; and the additive, the content of the aforesaid component may be 1 to 200 parts by weight, such as 5, 10, 20, 30, 40, 50, 60, 70, 80, 90, 100, 150 or 200 parts by weight.

For example, the composition of the present disclosure may further contain an inorganic filler to enhance the dimensional stability of articles made from the resin composition. The inorganic filler may be any inorganic filler known in the field to which this disclosure pertains, examples including but not limited to silica (fused, non-fused, porous or hollow type), aluminum oxide, aluminum hydroxide, magnesium oxide, magnesium hydroxide, calcium carbonate, aluminum nitride, boron nitride, aluminum silicon carbide, silicon carbide, titanium dioxide, zinc oxide, zirconium oxide, mica, boehmite (AlOOH), calcined talc, talc, silicon nitride, calcined kaolin, or a combination thereof. Moreover, the inorganic filler can be spherical, fibrous, plate-like, particulate, sheet-like or whisker-like in shape and can be optionally pretreated by a silane coupling agent.

For example, the composition of the present disclosure may further contain a curing accelerator to enhance the reactivity of the components in the composition. The curing accelerator (including curing initiator) may be any curing accelerator known in the field to which this disclosure pertains, examples including but not limited to catalysts such as a Lewis base, a Lewis acid or a combination thereof. The Lewis base may comprise any one or more of imidazole, boron trifluoride-amine complex, ethyltriphenyl phosphonium chloride, 2-methylimidazole (2MI), 2-phenyl-1H-imidazole (2PZ), 2-ethyl-4-methylimidazole (2E4 MI), triphenylphosphine (TPP) and 4-dimethylaminopyridine (DMAP). The Lewis acid may comprise metal salt compounds, such as those of manganese, iron, cobalt, nickel, copper and zinc, such as zinc octanoate or cobalt octanoate. The curing accelerator also includes a curing initiator, such as a peroxide capable of producing free radicals. The curing initiator may comprise dicumyl peroxide, tert-butyl peroxybenzoate, dibenzoyl peroxide, 2,5-dimethyl-2,5-di(tert-butylperoxy)-3-hexyne, bis(tert-butylperoxyisopropyl)benzene or a combination thereof, but not limited thereto.

For example, the composition of the present disclosure may further contain a solvent to adjust the viscosity of varnish formed therefrom. The solvent may comprise, but not limited to, methanol, ethanol, ethylene glycol monomethyl ether, acetone, butanone (methyl ethyl ketone), methyl isobutyl ketone, cyclohexanone, toluene, xylene, methoxyethyl acetate, ethoxyethyl acetate, propoxyethyl acetate, ethyl acetate, dimethylformamide, dimethylacetamide, propylene glycol methyl ether, or a mixture thereof.

For example, the composition of the present disclosure may further contain a silane coupling agent to promote dispersion of the inorganic filler. The silane coupling agent may comprise silane (such as but not limited to siloxane) and may be further categorized according to the functional groups into amino silane, epoxide silane, vinyl silane, acrylate silane, methacrylate silane, hydroxyl silane, isocyanate silane, methacryloxy silane and acryloxy silane.

The composition according to the present disclosure may be processed to make various articles, including but not limited to a prepreg, a resin film, a laminate or a printed circuit board. For example, the composition may be used to make a resin film by coating the composition on a carrier and then heating and baking to semi-cure the composition. The carrier may comprise a polyethylene terephthalate film (PET film), a polyimide film (PI film), a copper foil or a resin-coated copper (RCC). For example, the composition may be selectively coated on a polyethylene terephthalate film (PET film), a polyimide film (PI film), a copper foil or a resin-coated copper (RCC), followed by heating and baking to semi-cure the composition to form the resin film. For example, the composition may be used to make a laminate, which comprises two metal foils and an insulation layer disposed between the metal foils, wherein the insulation layer is made by curing the phosphorus-containing resin composition at high temperature and high pressure to the C-stage, a suitable curing temperature being for example between 150° C. and 220° C., and preferably between 190° C. and 210° C., and a suitable curing time being 90 to 180 minutes and preferably 90 to 150 minutes. The insulation layer may be obtained by curing the aforesaid prepreg or resin film. The metal foil may comprise copper, aluminum, nickel, platinum, silver, gold, or alloy thereof, such as a copper foil. For example, the laminate may be a copper-clad laminate (CCL).

In addition, the laminate may be further processed by trace formation processes to provide a printed circuit board (a.k.a. circuit board).

Generally, the composition according to the present disclosure or the article made therefrom may achieve one or more of the following features:

The articles made from the composition disclosed herein may have at least one, preferably at least two, more or all, of the following properties:
a glass transition temperature as measured by using a dynamic mechanical analyzer by reference to IPC-TM-650 2.4.24.4 of greater than or equal to 216° C., such as between 216° C. and 240° C. or between 220° C. and 230° C.; a ratio of thermal expansion in Z-axis as measured by using a thermomechanical analyzer by reference to IPC-TM-650 2.4.24.5 of less than or equal to 2.70%, such as between 2.20% and 2.70%; a copper foil peeling strength as measured by using a tensile strength tester by reference to IPC-TM-650 2.4.8 of greater than or equal to 3.0 lb/in, such as between 3.0 lb/in and 3.8 lb/in; no delamination occurrence after moisture absorption of 5 hours as measured by reference to IPC-TM-650 2.6.16.1 and then subject to a solder dip test by reference to IPC-TM-650 2.4.23; a dissipation factor as measured by reference to JIS C2565 of less than or equal to 0.0030 at 80 GHz; a dielectric constant as measured by reference to JIS C2565 of less than or equal to 3.10, such as between 2.50 and 3.10, or between 3.05 and 3.10; good stickiness resistance (no stickiness between prepregs) as measured from a plurality of prepregs vacuum-packed by an aluminum foil bag for storage at 35° C. constant temperature for 48 hours and then inspected visually to determine stickiness of the prepregs; and a shelf life of varnish made from the resin composition of greater than or equal to 1 day (no precipitation, turbidity or layer separation after 1 day), such as greater than or equal to 2, 3, 5, 7, 9, 11 or 15 days, as measured from a varnish made from the resin composition standing still at 5-35° C. and visually inspected for precipitation, turbidity or layer separation.

Most preferably the composition includes 40-80 parts by weight of vinyl terminated PPO; and 10-50 parts by weight of polybutadiene and 1-15 parts by weight of triallyl isocyanurate, wherein the flame retardant is 4-vinylbenzyl diphenylphosphine oxide, where PPO resin is SA9000 from Sabic and polybutadiene is a liquid resin with a number average of less than 5000 and minimum vinyl content of 20% and viscosity lower than 2000 poise at 45° C. and Li ion content less than 100 ppm.

### EXAMPLES

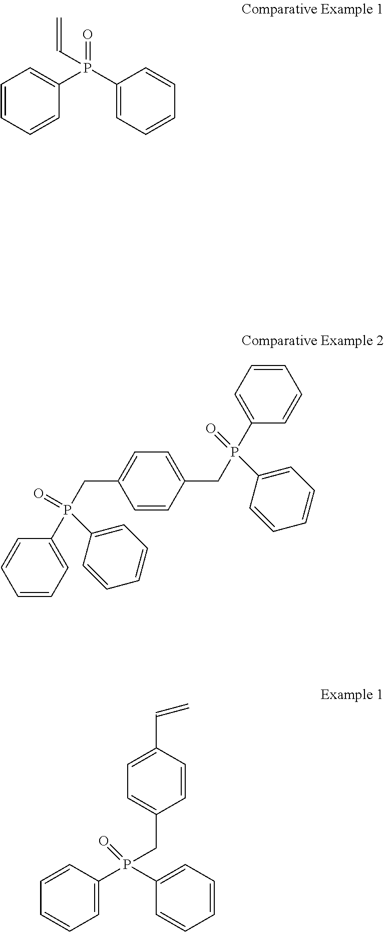 [SMILES: C=CP(=O)(c1ccccc1)c1ccccc1 ; O=P(Cc1ccc(CP(=O)(c2ccccc2)c2ccccc2)cc1)(c1ccccc1)c1ccccc1 ; C=Cc1ccc(CP(=O)(c2ccccc2)c2ccccc2)cc1]

Example of performance are listed in Table 1 of the attached document.

Formulation components were mixed at ratios listed in the Table 1, B staged at 150° C. for 3 minutes, milled and cured at 175° C. for 2 h then 190° C. for 1 h.

TABLE 1
Formulation and thermal properties comparison for
inventive Example 1 and Comparative Examples 1-3.

| | Comparative | Example 1 | Comparative | |
|---|---|---|---|---|
| | Example 1 | 4- | Example 2 | |
| | Vinyl | Vinylbenzyl | p-Xylylene | |
| | Diphenyl | Diphenyl | bis(diphenyl | Comparative |
| Formulation | Phosphine | Phosphine | phosphine | Example 3 |
| (wt %) | oxide | oxide | oxide), PQ 60 | No FR |
| SA9000 | 65.1 | 60.2 | 64.3 | 80.0 |
| B-1000 | 13.2 | 12.0 | 12.9 | 17.0 |
| TAIC | 3.2 | 3.0 | 3.2 | 3.0 |
| FR | 18.6 | 24.7 | 19.6 | — |
| Dicumyl | 1.0 | 1.0 | 1.0 | 1.0 |
| peroxide | | | | |
| Tg (° C.) | 182 | 186 | 222 | 170 |
| TGA (° C.) | | | | |
| 98% | 325 | 280 | 328 | 303 |
| 95% | 399 | 376 | 381 | 413 |
| 90% | 418 | 423 | 410 | 439 |
| Preliminary | Strong pass | Strong pass | Strong pass | Burned |
| Flame Test | | | | completely |

SA9000 (ex Sabic) Modified PPO with vinyl end-group
B1000 (ex NIPPON SODA) A homopolymer of butadiene
TAIC (ex Aldrich) 1,3,5-Triallyl-1,3,5-triazine-2,4,6(1H,3H,5H)-trione
Dicumyl peroxide (ex Aldrich)

Sample preparation: Samples of FR compound were combined with PPE resin SA9000 and crosslinking agents B-1000 and TAIC and cured on a small scale. Compositions of small-scale samples are shown in Table 1 above. Total % P was about 2.4%. Toluene was used as solvent. The sample was cured at 175° C. for 2 hours and post-cured at 190° C. for 1 hour. Thermal stability of the samples was studied using DSC and TGA.
Surprisingly preparation of uniform film using compound from comparative example 1 and 2 was difficult as seen above, however preparation of film using compound from Example 1 was easy and very uniform film was formed.

TABLE 3

| | Item | | | | | |
|---|---|---|---|---|---|---|
| | Comparative | | | | Comparative | Comparative |
| | Example 1 | | | Example 1 | Example 2 | Example 3 |
| | System | | | | | |
| | SA9000/FR | | | SA9000/FR | SA9000/FR | SA9000 |
| FR content | 25 phr | | | 25 phr | 25 phr | 0 phr |
| Dk@10 GHz | —* | 2.75 | 2.65 | 2.72 | 2.67 | 2.41 |
| Df@10 GHz | —* | 0.0049 | 0.0050 | 0.0025 | 0.0046 | 0.0018 |
| Dk@80 GHz | —* | 2.64 | 2.67 | 2.72 | 2.61 | 2.42 |
| Df@80 GHz | —* | 0.0049 | 0.0052 | 0.0022 | 0.0047 | 0.0020 |

*The quality is not good enough for test.
FR: Flame retardant
10 GHz: AET Microwave Dielectrometer.
80 GHz: Keycom MDM-03, FPR-50.

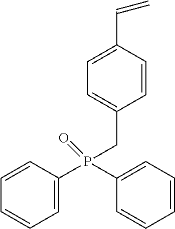 [SMILES: C=Cc1ccc(CP(=O)(c2ccccc2)c2ccccc2)cc1]

### Example 1—Prepared According to EP 0147724

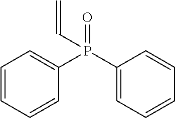 [SMILES: C=CP(=O)(c1ccccc1)c1ccccc1]

### Comparative Example 1—Prepared According to U.S. Pat. No. 3,035,096

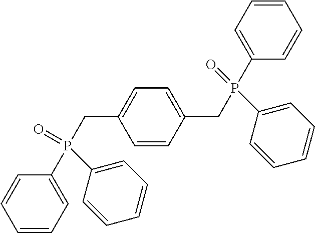 [SMILES: O=P(Cc1ccc(CP(=O)(c2ccccc2)c2ccccc2)cc1)(c1ccccc1)c1ccccc1]

### Comparative Example 2—Prepared According to U.S. Pat. No. 3,975,447

Although the present invention has been described with reference to particular means, materials and embodiments, from the foregoing description, one skilled in the art can easily ascertain the essential characteristics of the present invention and various changes and modifications can be made to adapt the various uses and characteristics without departing from the spirit and scope of the present invention as described above.

1. A composition comprising:
(a) a free radically polymerizable monomer or oligomer; and,
(b) 4-vinylbenzyl diphenylphosphine oxide having the formula (I): 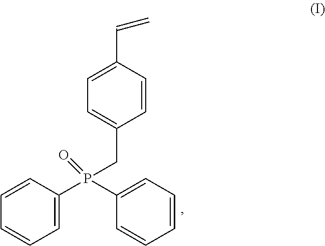 [SMILES: C=Cc1ccc(CP(=O)(c2ccccc2)c2ccccc2)cc1]
and wherein the composition is in the absence of a maleimide resin.

2. The composition of claim 1, wherein the free radically polymerizable monomer or oligomer contains a vinyl or allyl group.

3. The composition of claim 1, wherein the free radically polymerizable monomer or oligomer is an alkene or diene monomer or oligomer.

4. The composition of claim 1, wherein the free radically polymerizable monomer or oligomer comprises at least 40 weight percent of vinyl-terminated PPO.

5. The composition of claim 4, wherein the free radically polymerizable monomer or oligomer further comprises a further component which is selected from the group consisting of a vinyl-containing compound, an allyl containing compound, an acrylate resin, a polyoelfin, and combinations thereof.

6. The composition of claim 4, wherein the free radically polymerizable monomer or oligomer further comprises a further component which is selected from the group consisting of styrene, t-butyl styrene, divinylbenzene, bis(vinylbenzyl)ether, bis(vinylphenyl)ethane, 1,2,4-trivinylcyclohexane, polybutadiene, isoprene, polyisoprene, piperylene, trans-1,3-pentadiene, cis-1,3-pentadiene, 2-methyl-2-butene, dicyclopentadiene, cyclopentadiene, cyclopentene, triallyl isocyanurate, triallyl cyanurate, diallyl bisphenol A, allyl-modified tetramethylbiphenol, allyl-containing novolac resin, an allyl-containing dicycloisoprene novolac resin, dodecyl methacrylate, octadecyl methacrylate, 2-phenoxyethyl methacrylate, tricylcodecane dimethanol diacrylate, tricyclodecane di(meth)acrylate, 1,1-dodecanediol dimethacrylate, trimethylol-propane trimethacrylate, styrene-butadiene-divinylbenzene terpolymer, vinyl-polybutadiene-urethane oligomer, styrene-butadiene copolymer, hydrogenated styrene-butadiene copolymer, styrene-isoprene copolymer, polybutadiene, methyl styrene copolymer, styrene-ethylene copolymer, styrene-propylene copolymer, styrene-butadiene-isoprene terpolymer, hydrogenated styrene-butadiene terpolymer, hydrogenated styrene-isoprene copolymer, hydrogenated styrene-butadiene-isoprene terpolymer, and combinations thereof.

7. The composition of claim 1, further comprising at least one of a flame retardant, inorganic filler, curing accelerator, solvent, molecular weight regulator, polymerization inhibitor, toughening agent, coupling agent or a combination thereof.

8. The cured composition of claim 1.

9. Any one of a coating formulation, an encapsulant, a composite, an adhesive, a molding, a bonding sheet or a laminated plate comprising the composition of claim 1.

10. An article comprising the composition of claim 1.

11. The article of claim 10 wherein said article can be used in lead free soldering applications and electronic devices.

12. The article of claim 10 wherein the article further comprises a copper foil.

13. The article of claim 10 wherein said article is a printed circuit board.

14. A prepreg comprising the composition of claim 1.

15. The prepreg of claim 14 having a dielectric loss lower than or equal to 0.0030 at 80 GHz, a glass transition temperature of not lower than 180° C. and a thermal stability of not lower than 370° C. expressed as 5% weight loss in TGA.

16. A laminate or a bonding sheet comprising the composition of claim 1.

17. A printed wiring board comprising the prepreg of claim 14.

18. A printed wiring board comprising the prepreg of claim 14 having a dielectric loss lower than or equal to 0.0025 at 80 GHz, a glass transition temperature of not lower than 180° C. and a thermal stability of not lower than 370° C. expressed as 5% weight loss in TGA.

19. A printed wiring board comprising the laminate of claim 16.

20. A process of making a laminate that contains the composition of claim 1 comprising impregnating the composition into a filler material, to form a prepreg, followed by processing the prepreg at elevated temperature to promote partial cure to a B-stage and then laminating two or more of said prepregs at elevated pressure and temperature to form a laminate.
